(19) United States
(12) Patent Application Publication
(10) Pub. No.: US 2007/0131944 A1
(43) Pub. Date: Jun. 14, 2007

(54) Dual organic electroluminescent display and method of making same

(75) Inventors: Min-Chieh Hu, Shanhua Township (TW); Hsin-Ming Liao, Yangmei Township (TW)

Correspondence Address: WARE FRESSOLA VAN DER SLUYS &;ADOLPHSON, LLP, BRADFORD GREEN, BUILDING 5, 755 MAIN STREET, P O BOX 224, MONROE, CT, 06468, US

(73) Assignee: AU Optronics Corporation

(21) Appl. No.: 11/298,176

(22) Filed: Dec. 8, 2005

(51) Int. Cl. H01L 33/00

(52) U.S. Cl. 257/81

(57) ABSTRACT

A dual display unit comprising two OLED displays separately fabricated on two substrates. Each of the substrates has a peripheral area surrounding the respective display. A getter element is provided on one or both peripheral areas, substantially surrounding both the displays, for absorbing harmful gaseous elements in the display unit. A sealing material is applied along the edges of the two substrates enclosing the getter element so as to form a hermetic seal to the OLED displays. One or more further getter layers can be disposed between the first and second displays. The sealing material has a thickness sufficient to leave an air gap between the first display and the second display. The getter element and layers can be made of Group IA and Group IIA metals, and metal oxides, and can be disposed by a deposition process or a screen-printing spin coating

### FIELD OF THE INVENTION

The present invention pertains to organic electroluminescent display devices. Particularly, the present invention relates to organic light emitting diode (OLED) display devices and the methods of protecting dual screen OLED display devices from harmful gaseous elements in the surrounding environment.

### BACKGROUND OF THE INVENTION

Organic light emitting diode (OLED) display devices, including both polymer and small-molecule OLEDs, can be used for a great variety of displays, such as those used on lap-top computers, televisions, digital watches, telephones, pagers, cellular phones, calculators and the like. Generally, OLEDs have simple structures and they are relatively easy and inexpensive to fabricate. A basic OLED display unit includes a flat, transparent substrate, and a display area fabricated on the substrate.

For some applications, such as flip-style mobile phones, it is desirable to have more than one display screen. For example, a larger-size main display shows receiving and transmitting functions or images when the handset is in use, while a smaller-size secondary display shows status information in a stand-by mode and shows information of an incoming call before the user answers. In a flip-style phone, for example, the two displays can be arranged back-to-back on the flip cover. For this kind of application, it is highly desirable that the total thickness of the two displays is minimized. Preferably, the two displays form a single module so that they can be easily assembled into the phone unit.

Certain OLED structure components, such as reactive metal cathode layer and organic light emitting materials, are susceptible to oxygen and moisture, which exist in the ambient atmosphere. Oxygen and moisture can produce deleterious effects that severely limit the lifetime of the display device. In order to maintain a satisfactory performance over an extended period of time, the active structure of an OLED display area must be protected to prevent water vapor and oxygen from penetrating the structure. It is known in the art to use organic or inorganic materials to form a protective layer surrounding the active OLED layers, for protection against those harmful gaseous elements. Examples of such protective layers can be found in Affinito (U.S. Pat. No. 6,268,695) and Graff et al. (U.S. Pat. No. 6,570,325). These protective layers are usually only a few hundred nanometers thick. They offer a moderate degree of protection.

For an improved protection, an OLED display area may be encapsulated between two solid plates. One of the plates may be the substrate itself and another may be a plate of an organic or inorganic material that is sealed onto the display area by an adhesive.

Brown et al. (U.S. Pat. No. 6,835,950) discloses some examples of the encapsulated OLED display area. In some of embodiments as disclosed in Brown et al., an adhesive layer is disposed directly on the OLED layer. In other embodiments, a protective layer made of organometallic materials, silicon compounds, or metal oxides is disposed between the adhesive layer and the OLED layer. Brown et al. also discloses the use of a getter material in the OLED display. The getter material is a material that reacts readily with active gases including water vapor and oxygen, forming stable low-vapor-pressure chemical compounds so as to remove the active gases from the gas phase. Preferred getter materials include Group IIA metals and metal oxides, such as calcium (Ca), barium (Ba), calcium oxide (CaO), and barium oxide (BaO). However, Brown et al., Affinito , and Graff et al only disclose a display module having a single OLED display.

A dual display module has two OLED displays, each of which is fabricated on a different substrate. In general, the displays are not encapsulated individually. Rather, a dual-display module is made by arranging the two display modules back-to-back such that the display areas are encapsulated between the two substrates. An adhesive material is used to provide a hermetic seal along the edges of the substrates. A simplified structure of a hermetically sealed dual-type display unit is shown in FIG. 1. As shown, the display unit 100 includes a main display 120 fabricated on a substrate 110 and a secondary display 140 fabricated on a substrate 130. The two displays are arranged back-to-back and joined at the edges of the substrates by a sealing member 150, which forms a hermetic seal to protect the displays from undesirable elements in the environment. Each of the display areas 120 and 140 includes a light-emitting pixel region with a “cathode/light emitting layers/anode” structure, which is known in the art. It may also include additional materials such as protective layers disposed on the top of the structure. Each of the substrates 110 and 130 may also include additional layers of materials disposed on either of the surfaces.

During the encapsulating process, some air and moisture may become trapped inside the dual display unit. A trace amount of moisture and air may also infiltrate through the sealing material to reach the display areas over time. In order to reduce the amount of water vapor and oxygen within the encapsulated module, a getter material is also included inside the sealed area.

Kim et al. (U.S. Patent Application Publication No. 2004/0119740 A1) discloses a number of dual-type OLED devices that include a water-absorbing material. In one of the embodiments, as shown in FIG. 2a and FIG. 2b, the substrate 130 has a recessed area 141 for disposing an amount of getter material 142. In another embodiment, as shown in FIG. 3, the OLED display 120 on the substrate 110 is surrounded by a passivation layer 126, and the OLED display 140 on the substrate 130 is surrounded by another passivation layer 146. An absorbent sheet (not shown) is disposed between the two passivation layers. In these embodiments, the placement of the water-absorbing material may not be adequate.

### SUMMARY OF THE INVENTION

The present invention provides a dual OLED display unit comprising two OLED displays separately fabricated on two substrates. Each of the substrates has a peripheral area surrounding the OLED display. A sealing material is used to form a hermetic seal around the OLED displays. A getter material is provided on one or both substrates for absorbing harmful gaseous elements. The getter material is disposed on the peripheral areas at least between the displays and the sealing material. The getter material may also be disposed between the OLED displays. Because the getter material may expand as it absorbs water vapor, the OLED displays may experience a surface pressure due to the expanding getter material. Thus, a gap is provided between the two displays to allow for the expansion of the getter material over time.

### BRIEF DESCRIPTION OF THE DRAWINGS

The above and other objects, features and advantages of the present invention will become apparent from a consideration of the subsequent detailed description presented in connection with accompanying drawings, in which:

FIG. 1 is a simplified structure of a hermetically sealed dual panel display device;

FIG. 2a is a cross sectional view of a prior art dual panel display device;

FIG. 2b is a plan view of one of the display areas of FIG. 2a;

FIG. 3 is a cross sectional view of another prior art dual panel display device;

FIGS. 4a-4c are cross sectional views of the dual panel display devices according to the first embodiment of the present invention;

FIG. 4d is a plan view of a display area of FIG. 4a to FIG. 4c;

FIG. 5 is a cross sectional view of a dual panel display device according to the second embodiment of the present invention; and

FIG. 5a is a detailed cross sectional view of the circled area in FIG. 5.

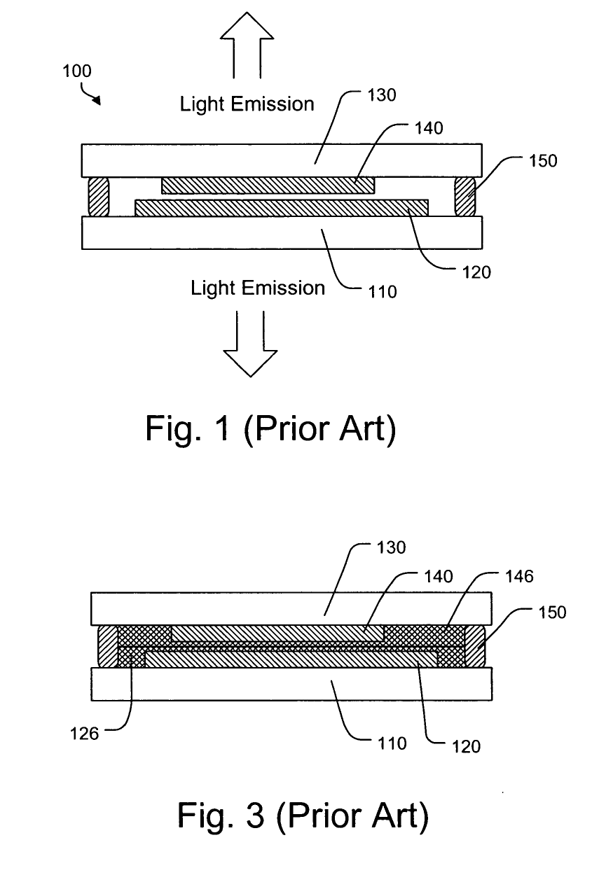

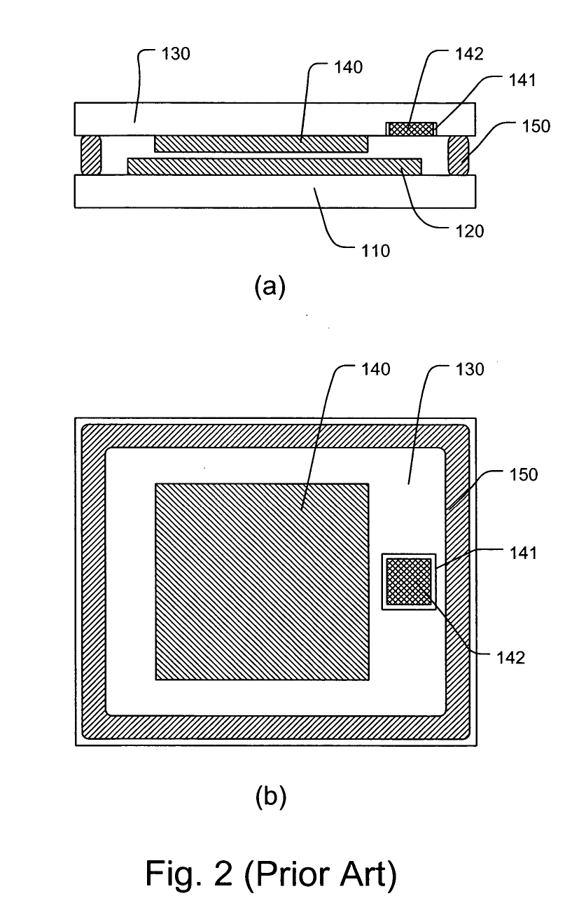

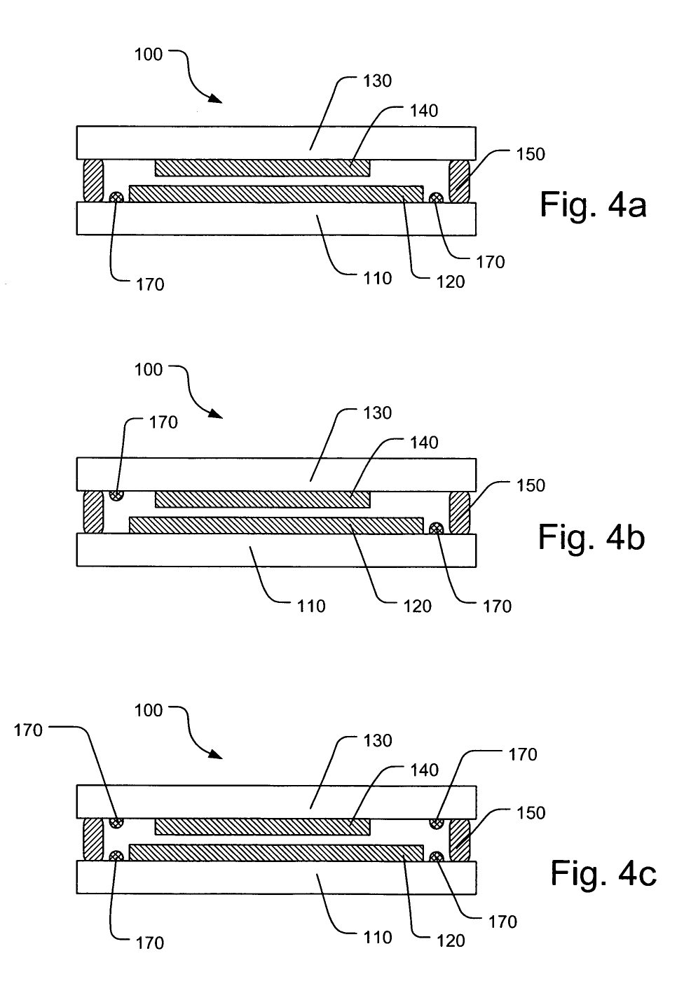

### DETAILED DESCRIPTION OF THE INVENTION

The dual display panel of the present invention comprises a first display area on a first substrate and a second display area on a second substrate. A sealing material is disposed between the two substrates to provide a hermetic seal and a getter material is used to absorb water vapor and oxygen within the sealed area.

The present invention can be achieved in numerous ways, especially through the following exemplary embodiments.

### FIRST EMBODIMENT OF THE INVENTION

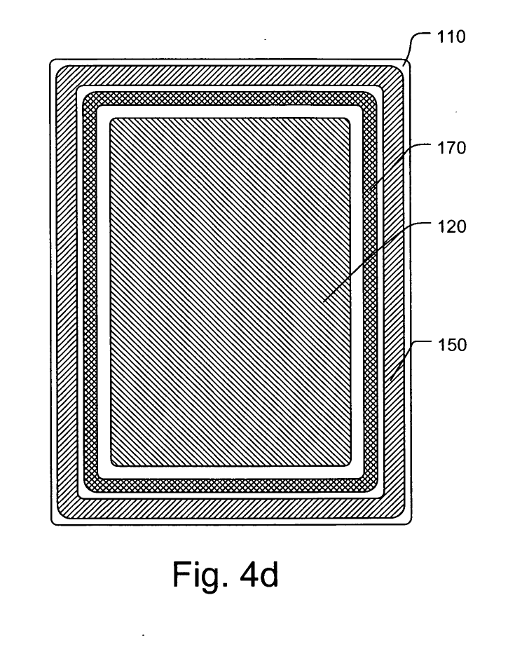

The first embodiment of the present invention is depicted in FIGS. 4a to 4d. A first display area 120 having a typical “cathode/light emitting layers/anode” pixel array structure (structure not shown in the figures) is fabricated on a first substrate 110. A second display area 140 is fabricated on a second substrate 130. The first display area 120 and the second display area 140 are joined in a back-to-back fashion by an adhesive material 150 disposed around the edges of the substrates 110 and 130, so as to form a hermetically sealed dual display unit 100. On the inner side of one or both of the substrates, a band of getter material 170 is disposed to form an enclosed ring around both the display areas 120, 140. As shown, the getter material is disposed on a peripheral area of one or both substrates substantially surrounding the respective display areas. The adhesive material 150 can be a UV curable material, a thermal curable material, or a pressure curable material, for example.

Preferred getter materials include Group IA metals, Group IIA metals and metal oxides, such as calcium (Ca), barium (Ba), calcium oxide (CaO), and barium oxide (BaO). Preferably, the getter band is coated on one or both of the substrates 110 and 130 using a predetermined mask to form a pattern as desired. It can be formed entirely on the substrate of one of the displays (as shown in FIG. 4a), partly on one substrate and partly on another substrate (as shown in FIG. 4b), or on both substrates (as shown in FIG. 4c). Preferred coating methods include thermal deposition, physical vapor deposition (PVD), chemical vapor deposition (CVD), plasma enhanced chemical vapor deposition (PECVD), and screen-printing spin coating.

A schematic plan view of a display area with the getter band disposed in its peripheral area around the display area is shown in FIG. 4d. As shown, when the two displays are sealed back-to-back by the sealing material 150, the getter material is enclosed to form a water vapor and oxygen barrier surrounding the display areas. As such, the water vapor and oxygen infiltrating the sealing member 150 may be absorbed before they migrate toward the display areas.

### SECOND EMBODIMENT OF THE INVENTION

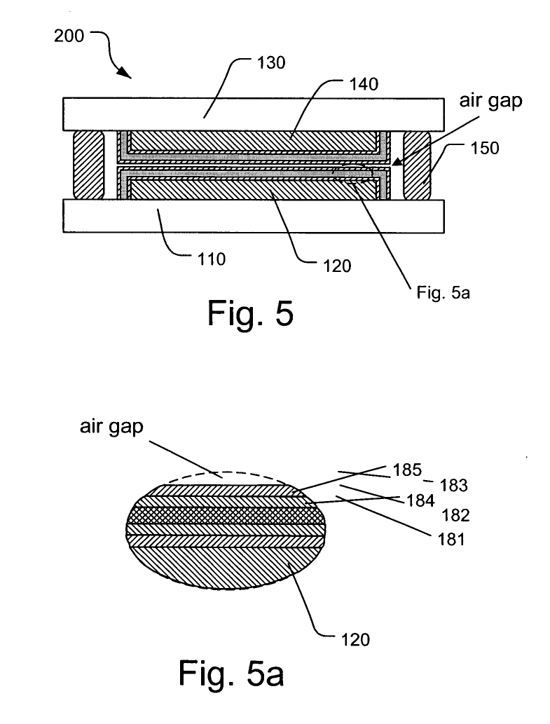

Referring now to FIG. 5, in the second embodiment of the present invention, a first display area 120 is fabricated on a first substrate 110. A second display 140 is fabricated on a second substrate 130. The first display 120 and the second display 140 are joined back-to-back by an adhesive member 150 around the edges of the substrates 110 and 130 to form a hermetically sealed dual display unit 200. A stack of layers is deposited on and around each of the first display area 120 and the second display area 140. One example of the detailed structure of the stack is shown in FIG. 5a. The stack comprises, from the surface of the display area 120, a first planarizing or smoothing layer 181, a first protective layer 182 and a getter layer 183. The planarizing layer—protective layer pair may comprise one or more layers of organic and/or inorganic materials. Suitable materials for this layer pair include silicon oxide, silicon nitride, silicon oxynitride, silicon carbide, metal oxide, organic compound, organic metal compound, and polymers such as PVC, acrylics or teflon-like. Specifically, the organic material has the merit of preventing diffusion that usually occurs at the interface of various layers, while the organic material can favorably release the stress on the layer. The materials suitable for the getter layer 183 include Group IA metals, Group IIA metals and metal oxides, such as calcium (Ca), barium (Ba), calcium oxide (CaO), and barium oxide (BaO). It should be noted that layer 181 can also be a protective layer and layer 182 can also be a planarizing layer. Furthermore, one or more protective and planarizing layers can be deposited on top of the getter layer 183, as shown in FIG. 5a.

The layers in the stack are preferably deposited by using chemical vapor deposition (CVD), plasma enhanced chemical vapor deposition (PECVD), or physical vapor deposition (PVD). Techniques for deposition of materials are known to persons skilled in the art, and the scope of the present invention is not intended to be limited to any particular type or kind thereof.

The sealing member 150 is arranged such that when the display unit is hermetically sealed, an air gap between the top layer of the first display area and the top layer of the second display area exists to prevent these two displays from contacting each other, even after the thickness of the getter layer has changed as the result of absorbing water and/or oxygen.

It is to be understood that the above-described arrangements are only illustrative of the principles of the present invention. Although the present invention has been described and illustrated with respect to exemplary embodiments thereof, the foregoing and various other additions and omissions may be made therein without departing from the spirit and scope of the present invention.

What is claimed is:

1. A dual display unit, comprising:
a first display area on a first substrate;
a second display area on a second substrate, wherein each of the first and second substrates has a peripheral area surrounding the respective display area;
a getter element disposed at least on one of the peripheral areas, substantially surrounding the first and the second display areas; and
a sealing material disposed at least partly on the peripheral area of the first substrate and on the peripheral area of the second substrate enclosing the getter element so as to form a hermetic seal to the first display and the second display.

2. The dual display unit as in claim 1, wherein at least one of the display areas is an organic light emitting diode (OLED) display device.

3. The dual display unit as in claim 1, wherein at least one of the display areas is a polymeric light emitting diode (PLED) display device.

4. The dual display unit as in claim 1, wherein the getter element is deposited on the peripheral areas of the first substrate and the second substrate.

5. The dual display unit as in claim 1, wherein the getter element further comprises a getter layer disposed between the first display and the second display.

6. The dual display unit as in claim 1, wherein the getter element further comprises a first getter layer disposed on the first display area and a second getter layer disposed on the second display area.

7. The dual display unit as in claim 6, further comprising:
a first protective layer disposed between the first getter layer and the first display area; and
a second protective layer disposed between the second getter layer and the second display area.

8. The dual display unit as in claim 1, wherein the sealing material comprises an adhesive material.

9. The dual display unit as in claim 1, wherein the getter element is made of at least one Group IA metal.

10. The dual display unit as in claim 1, wherein the getter element is made of at least one Group IIA metal.

11. The dual display unit as in claim 1, wherein the getter element is made of one or more metal oxides.

12. A method for producing a dual display unit, comprising the steps of:
arranging a first display area on a first substrate and a second display area on a second substrate, wherein each of the first and second substrates is dimensioned to have a peripheral area surrounding the respective display area;
providing a getter element at least on one of the peripheral areas, substantially surrounding the first and the second display areas; and
disposing a sealing material at least partly on the peripheral area of the first substrate and on the peripheral area of the second substrate enclosing the getter element so as to form a hermetic seal to the first display and the second display.

13. The method as in claim 12, wherein the getter element is provided by a deposition process.

14. The method as in claim 12, wherein the getter element is provided by a screen-printing or spin coating.

15. The method as in claim 12, wherein the getter element comprises a getter layer provided between the first display area and the second display area.

16. The method as in claim 12, wherein said arranging comprises disposing an organic light emitting diode (OLED) display device in the first display area and disposing another organic light emitting diode (OLED) display device in the second display area.

17. The method as in claim 12, wherein said arranging comprises disposing a polymeric light emitting diode (PLED) display device in the first display area and disposing another polymeric light emitting diode (PLED) display device in the second display area.

18. The method as in claim 12, wherein the getter element further comprises a first getter layer disposed on the first display area and a second getter layer disposed on the second display area.

19. The method as in claim 18, further comprising the step of disposing a first protective layer between the first getter layer and the first display area and disposing a second protective layer between the second getter layer and the second display area.

20. The method as in claim 12, wherein the sealing material comprises an adhesive material.
